(19) United States
(12) Patent Application Publication
(10) Pub. No.: US 2018/0190860 A1
(43) Pub. Date: Jul. 5, 2018

(54) SYSTEM AND METHOD FOR CLEAVING PHOTOVOLTAIC STRUCTURES

(71) Applicant: SolarCity Corporation, San Mateo, CA (US)

(72) Inventors: Seth M. Winger, Palo Alto, CA (US); Bobby Yang, Los Altos Hills, CA (US); Peter P. Nguyen, San Jose, CA (US); Zheng Xu, Pleasanton, CA (US)

(73) Assignee: SolarCity Corporation, San Mateo, CA (US)

(21) Appl. No.: 15/465,419

(22) Filed: Mar. 21, 2017

Related U.S. Application Data
(60) Provisional application No. 62/442,885, filed on Jan. 5, 2017.

(51) Int. Cl. H01L 31/18; H01L 21/683; H01L 21/67; H01L 31/05; B32B 43/00

(52) U.S. Cl. CPC H01L 31/1876; H01L 21/6838; B32B 2457/12; H01L 31/0516; B32B 43/006; H01L 21/67092

(57) ABSTRACT

A cleaving apparatus for cleaving a photovoltaic structure into multiple strips is described. The apparatus can include a supporting post and a cleaving platform for cleaving the photovoltaic structure. The cleaving platform can be coupled to the supporting post via a translation stage and can include multiple platform segments that are configured to move relative to each other during cleaving. Each of the multiple platform segments can include a wafer-holding surface for holding at least a portion of the photovoltaic structure.

### CROSS-REFERENCE TO OTHER APPLICATIONS

This claims the benefit of U.S. Provisional Patent Application No. 62/442,885, Attorney Docket No. P349-1PUS, entitled “SYSTEM AND METHOD FOR CLEAVING PHOTOVOLTAIC STRUCTURES,” filed Jan. 5, 2017, the disclosure of which is incorporated herein by reference in its entirety for all purposes.

This is related to U.S. Provisional Patent Application No. 62/088,509, Attorney Docket Number P103-1PUS, entitled “SYSTEM, METHOD, AND APPARATUS FOR AUTOMATIC MANUFACTURING OF SOLAR PANELS,” filed Dec. 5, 2014; U.S. Provisional Patent Application No. 62/143,694, Attorney Docket Number P103-2PUS, entitled “SYSTEMS AND METHODS FOR PRECISION AUTOMATION OF MANUFACTURING SOLAR PANELS,” filed Apr. 6, 2015; U.S. patent application Ser. No. 14/826,129, Attorney Docket Number P103-3NUS, entitled “PHOTOVOLTAIC STRUCTURE CLEAVING SYSTEM” filed Aug. 13, 2015; U.S. patent application Ser. No. 14/563,867, Attorney Docket Number P67-3NUS, entitled “HIGH EFFICIENCY SOLAR PANEL” filed Dec. 8, 2014; and U.S. patent application Ser. No. 14/510,008, Attorney Docket Number P67-2NUS, entitled “MODULE FABRICATION OF SOLAR CELLS WITH LOW RESISTIVITY ELECTRODES,” filed Oct. 8, 2014, the disclosures of which are incorporated herein by reference in their entirety for all purposes.

### FIELD OF THE INVENTION

This is generally related to solar panel fabrication, including cleaving a photovoltaic structure into multiple strips.

### Definitions

“Solar cell” or “cell” is a photovoltaic structure capable of converting light into electricity. A cell may have any size and any shape, and may be created from a variety of materials. For example, a solar cell may be a photovoltaic structure fabricated on a silicon wafer or one or more thin films on a substrate material (e.g., glass, plastic, or any other material capable of supporting the photovoltaic structure), or a combination thereof.

A “solar cell strip,” “photovoltaic strip,” or “strip” is a portion or segment of a photovoltaic structure, such as a solar cell. A solar cell may be divided into a number of strips. A strip may have any shape and any size. The width and length of a strip may be the same or different from each other. Strips may be formed by further dividing a previously divided strip.

A “cascade” is a physical arrangement of solar cells or strips that are electrically coupled via electrodes on or near their edges. There are many ways to physically connect adjacent photovoltaic structures. One way is to physically overlap them at or near the edges (e.g., one edge on the positive side and another edge on the negative side) of adjacent structures. This overlapping process is sometimes referred to as “shingling.” Two or more cascading photovoltaic structures or strips can be referred to as a “cascaded string,” or more simply as a string.

“Finger lines,” “finger electrodes,” and “fingers” refer to elongated, electrically conductive (e.g., metallic) electrodes of a photovoltaic structure for collecting carriers.

A “busbar,” “bus line,” or “bus electrode” refers to an elongated, electrically conductive (e.g., metallic) electrode of a photovoltaic structure for aggregating current collected by two or more finger lines. A busbar is usually wider than a finger line, and can be deposited or otherwise positioned anywhere on or within the photovoltaic structure. A single photovoltaic structure may have one or more busbars.

A “photovoltaic structure” can refer to a solar cell, a segment, or a solar cell strip. A photovoltaic structure is not limited to a device fabricated by a particular method. For example, a photovoltaic structure can be a crystalline silicon-based solar cell, a thin film solar cell, an amorphous silicon-based solar cell, a poly-crystalline silicon-based solar cell, or a strip thereof.

### BACKGROUND

Advances in photovoltaic technology, which are used to make solar panels, have helped solar energy gain mass appeal among those wishing to reduce their carbon footprint and decrease their monthly energy costs. However, the panels are typically fabricated manually, which is a time-consuming and error-prone process that makes it costly to mass-produce reliable solar panels.

Solar panels typically include one or more strings of complete solar cells. Adjacent solar cells in a string may overlap one another in a cascading arrangement. For example, continuous strings of solar cells that form a solar panel are described in U.S. patent application Ser. No. 14/510,008, filed Oct. 8, 2014, and entitled “MODULE FABRICATION OF SOLAR CELLS WITH LOW RESISTIVITY ELECTRODES,” the disclosure of which is incorporated herein by reference in its entirety. Producing solar panels with a cascaded cell arrangement can reduce the resistance due to interconnections between the strips, and can increase the number of solar cells that can fit into a solar panel.

One method of making such a panel includes sequentially connecting the busbars of adjacent cells and combining them. One type of panel (as described in the above-noted patent application) includes a series of cascaded strips created by dividing complete solar cells into strips, and then cascading the strips to form one or more strings.

Precise and consistent division of solar cells into strips and alignment of strips or cells when forming a cascade arrangement is critical to ensuring proper electrical and physical connections, but such alignment can be difficult to achieve reliably in high volumes if performed manually.

### SUMMARY

One embodiment of the invention provides an apparatus for cleaving a photovoltaic structure into multiple strips. The apparatus can include a supporting post and a cleaving platform for cleaving the photovoltaic structure. The cleaving platform can be coupled to the supporting post via a translation stage and can include multiple platform segments that are configured to move relative to each other during cleaving. Each of the multiple platform segments can include a wafer-holding surface for holding at least a portion of the photovoltaic structure.

In a variation on this embodiment, prior to cleaving the photovoltaic structure, the cleaving platform can be configured to hold the photovoltaic structure with wafer-holding surfaces of the multiple platform segments substantially aligned.

In a further embodiment, the photovoltaic structure can be held in such a way that a scribed groove on the photovoltaic structure is substantially parallel to and positioned below a gap separating two adjacent platform segments.

In a variation on this embodiment, during cleaving at least one platform segment of the cleaving platform can rotate around an adjacent edge of an adjacent platform segment.

In a variation on this embodiment, the multiple platform segments can include a stationary center segment and two movable side segments positioned on each side of the stationary center segment.

In a further embodiment, the two movable side segments can be configured to rotate around adjacent edges of the stationary center segment, cleaving the photovoltaic structure into three strips.

In a further embodiment, the apparatus can further include a vertical actuator coupled to each movable side segment via a cam-follower mechanism, which can be configured to convert vertical movements of the vertical actuator to rotations of the movable side segments.

In a variation on this embodiment, the wafer-holding surface can include a plurality of vacuum cups configured to apply a suction force on the portion of the photovoltaic structure.

In a variation on this embodiment, the multiple platform segments comprise a stationary platform segment and at least one movable platform segment. The apparatus can further include a counterforce-applying mechanism.

During cleaving, at least a portion of the photovoltaic structure is sandwiched between the counterforce-applying mechanism and the stationary platform segment.

In a variation on this embodiment, the apparatus can include a conveyor configured to transport the photovoltaic structure to a position below the cleaving platform to allow the cleaving platform to be lowered by the translation stage to pick up the photovoltaic structure.

### BRIEF DESCRIPTION OF THE FIGURES

FIG. 1A shows an exemplary grid pattern on the front surface of a photovoltaic structure, according to one embodiment.

FIG. 1B shows an exemplary grid pattern on the back surface of a photovoltaic structure, according to one embodiment.

FIG. 1C shows multiple strips, which are the result of separating a photovoltaic structure along a set of grooves.

FIG. 1D shows one example of a groove that can prevent damage to the emitter junction of a photovoltaic structure during a cleaving process.

FIG. 2A shows a string of cascaded strips, according to one embodiment.

FIG. 2B shows a side view of the string of cascaded strips, according to one embodiment.

FIG. 3A illustrates the perspective view of an exemplary cleaving system, according to one embodiment.

FIG. 3B shows the side view of the exemplary cleaving system with the cleaving platform configured in the “open” position, according to one embodiment.

FIG. 3C shows an amplified view of the cleaving platform, according to one embodiment.

FIG. 3D shows an amplified view of the bottom section of a platform segment, according to one embodiment.

FIG. 3E shows the bottom view of bottom section 330, according to one embodiment.

FIG. 3F shows the side view of bottom section 330, according to one embodiment.

FIG. 3G shows the placement of a to-be-cleaved wafer with respect to the cleaving platform, according to one embodiment.

FIG. 4A illustrates the side view of the exemplary cleaving system with the cleaving platform configured in the “closed” position, according to one embodiment.

FIG. 4B shows an amplified view of the cleaving platform in the closed position, according to one embodiment.

FIG. 4C shows the side view of the cleaving platform in the closed position, according to one embodiment.

FIG. 4D shows the perspective view of the wafer strips, according to one embodiment.

FIG. 5A shows the side view of the cleaving platform along with the actuator and motion transmission system, according to one embodiment.

FIG. 5B shows the perspective view of the cleaving platform along with the actuator and motion transmission system, according to one embodiment.

FIG. 6A shows the supporting mechanism positioned below the cleaving platform, according to one embodiment.

FIG. 6B shows the side view of the supporting mechanism positioned below the cleaving platform, according to one embodiment.

FIG. 7A shows the perspective view of the supporting mechanism, according to one embodiment.

FIG. 7B shows the side view of the supporting mechanism, according to one embodiment.

FIG. 8 shows the opposing forces applied to a wafer during cleaving, according to one embodiment.

FIG. 9A shows the partial front view of a cleaving system incorporating a conveyor before cleaving, according to one embodiment.

FIG. 9B shows the partial front view of the cleaving system incorporating a conveyor during cleaving, according to one embodiment.

FIG. 9C shows the top view of the conveyor and supporting mechanism, according to one embodiment.

FIG. 9D shows the partial side view of the cleaving system incorporating a conveyor after cleaving, according to one embodiment.

FIG. 9E shows the strips of the cleaved wafer placed on the conveyor, according to one embodiment.

FIG. 10 presents a flowchart illustrating the cleaving process, according to one embodiment.

FIG. 11 shows an exemplary controlling apparatus that can facilitate cleaving a photovoltaic structure into multiple strips, according to one embodiment.

FIG. 12 shows a sequence of steps for processing photovoltaic structures to produce a string, according to one embodiment.

In the figures, like reference numerals refer to the same figure elements.

### DETAILED DESCRIPTION

The following description is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present disclosure. Thus, the invention is not limited to the embodiments shown, but is to be accorded the widest scope consistent with the principles and features disclosed herein.

### Overview

A cleaving system is provided that automatically divides a photovoltaic structure into multiple strips without significantly damaging the individual strips. The cleaving system can operate within an automated assembly line that can manufacture complete solar panels, which may include photovoltaic structure strips arranged in a cascaded configuration.

The cleaving system can receive a photovoltaic structure that has been scribed along a blank space next to or near a busbar of the photovoltaic structure. The groove may have any orientation with respect to the busbar, but is normally substantially parallel to it. The photovoltaic structure may include one or more grooves. The cleaving system can divide the photovoltaic structure into two or more strips by breaking the photovoltaic structure along at least one scribed groove. In some embodiments, the cleaving system can include a wafer-holding mechanism for picking up and holding the scribed photovoltaic structure.

The wafer-holding mechanism can be built into a platform that includes a stationary portion and at least one movable portion. During operation, while the wafer-holding mechanism is holding the scribed photovoltaic structure in midair, the movable portion of the platform can rotate, breaking the photovoltaic structure along a scribed groove. The platform is designed in such a way that the scribed groove is positioned substantially below a gap between the stationary portion and the movable portion. In some embodiments, the cleaving system can include another supporting mechanism positioned on the opposite side of the photovoltaic structure. More specifically, the supporting mechanism is positioned directly opposite to the stationary portion of the platform, providing a counter force against the movement of the movable portion of the platform.

Later stages of the solar-panel assembly line may arrange a plurality of strips into one or more cascaded strings, and may then combine multiple strings to form a solar panel.

### Solar Panel Based on Cascaded Strips

As described in U.S. patent application Ser. No. 14/563,867, a solar panel can have multiple (such as three) strings, each string including cascaded strips, connected in parallel. Such a multiple-parallel-string panel configuration can provide the same output voltage with a reduced internal resistance. In general, a cell can be divided into a number of (e.g., n) strips, and a panel can contain a number of strings (the number of strings can be the same as or different from the number of strips in the cell). If a string has the same number of strips as the number of regular photovoltaic structures in a conventional single-string panel, the string can output approximately the same voltage as a conventional panel. Multiple strings can be connected in parallel to form a panel. If the number of strings in a panel is the same as the number of strips in the cell, the solar panel can output roughly the same current as a conventional panel. On the other hand, the panel's total internal resistance can be a fraction (e.g., 1/n) of the resistance of a string. Therefore, in general, the greater n is, the lower the total internal resistance of the panel, and the more power one can extract from the panel. However, a tradeoff is that as n increases, the number of connections required to interconnect the strings also increases, which increases the amount of contact resistance. Also, the greater n is, the more strips a single cell needs to be divided into, which increases the associated production cost and decreases overall reliability due to the larger number of strips used in a single panel.

Another consideration in determining n is the contact resistance between the electrode and the photovoltaic structure on which the electrode is formed. The greater this contact resistance, the greater n might need to be to reduce effectively the panel's overall internal resistance. Hence, for a particular type of electrode, different values of n might be needed to attain sufficient benefit in reduced total panel internal resistance to offset the increased production cost and reduced reliability. For example, conventional silver-paste or aluminum based electrodes may require n to be greater than four, because the process of screen printing and firing silver paste onto a cell does not produce ideal resistance between the electrode and underlying photovoltaic structure. In some embodiments of the present invention, the electrodes, including both the busbars and finger lines, can be fabricated using a combination of physical vapor deposition (PVD) and electroplating of copper as an electrode material. The resulting copper electrode can exhibit lower resistance than an aluminum or screen-printed-silver-paste electrode. Consequently, a smaller n can be used to attain the benefit of reduced panel internal resistance. In some embodiments, n is selected to be three, which is less than the n value generally needed for cells with silver-paste electrodes or other types of electrodes. Correspondingly, two grooves can be scribed on a single cell to allow the cell to be divided into three strips.

In addition to lower contact resistance, electro-plated copper electrodes can also offer better tolerance to micro cracks, which may occur during a cleaving process. Such micro cracks might adversely impact silver-paste-electrode cells. Plated-copper electrode, on the other hand, can preserve the conductivity across the cell surface even if there are micro cracks in the photovoltaic structure. The copper electrode's higher tolerance for micro cracks allows one to use thinner silicon wafers to manufacture cells. As a result, the grooves to be scribed on a cell can be shallower than the grooves scribed on a thicker wafer, which in turn helps increase the throughput of the scribing process. More details on using copper plating to form a low-resistance electrode on a photovoltaic structure are provided in U.S. patent application Ser. No. 13/220,532, entitled “SOLAR CELL WITH ELECTROPLATED GRID,” filed Aug. 29, 2011, the disclosure of which is incorporated herein by reference in its entirety.

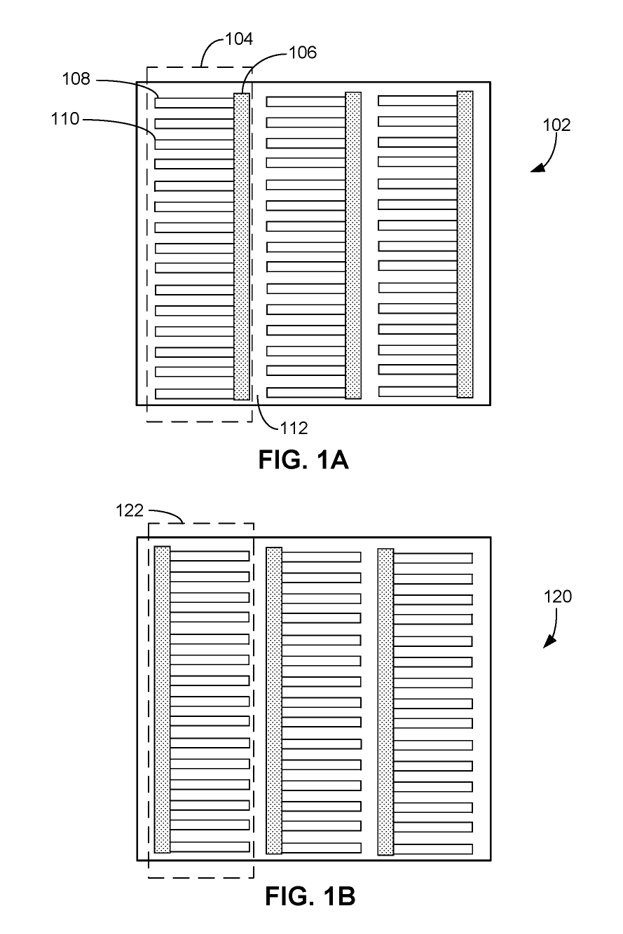

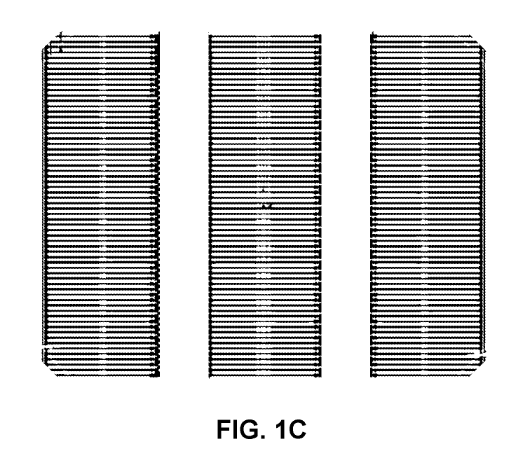

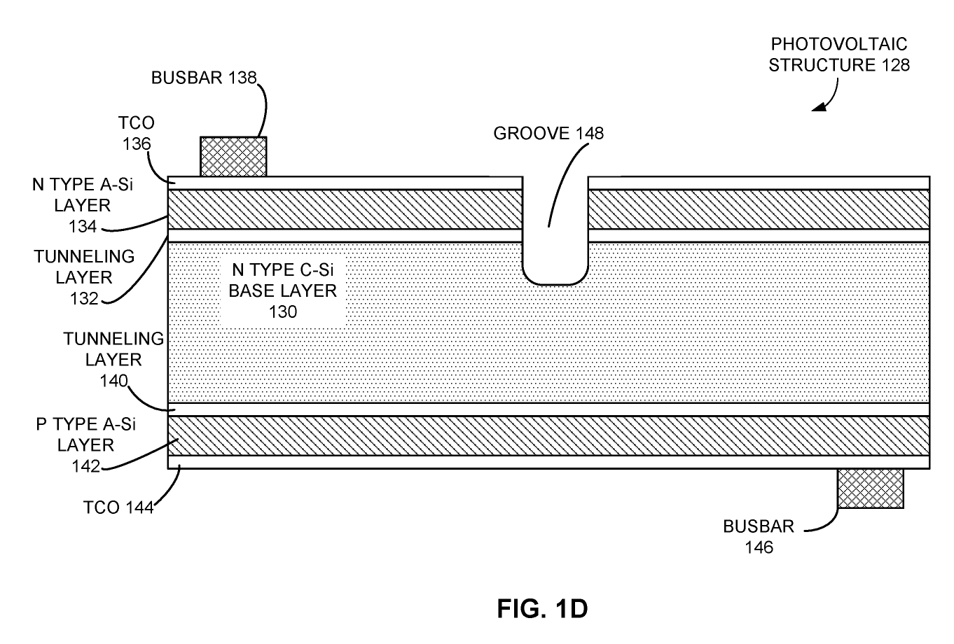

FIG. 1A shows an exemplary grid pattern on the front surface of a photovoltaic structure, according to one embodiment of the present invention. In the example shown in FIG. 1A, grid 102 includes three sub-grids, such as sub-grid 104. This three sub-grid configuration allows the photovoltaic structure to be divided into three strips. To enable cascading, each sub-grid needs to have an edge busbar, which can be located either at or near the edge. In the example shown in FIG. 1A, each sub-grid includes an edge busbar (“edge” here refers to the edge of a respective strip) running along the longer edge of the corresponding strip and a plurality of parallel finger lines running in a direction parallel to the shorter edge of the strip. For example, sub-grid 104 can include edge busbar 106, and a plurality of finger lines, such as finger lines 108 and 110. To facilitate the subsequent laser-assisted scribe-and-cleave process, a predefined blank space (i.e., space not covered by electrodes) is inserted between the adjacent sub-grids. For example, blank space 112 is defined to separate sub-grid 104 from its adjacent sub-grid. In some embodiments, the width of the blank space, such as blank space 112, can be between 0.1 mm and 5 mm, preferably between 0.5 mm and 2 mm. There is a tradeoff between a wider space that leads to a more tolerant scribing operation and a narrower space that leads to more effective current collection. In a further embodiment, the width of such a blank space can be approximately 1 mm.

FIG. 1B shows an exemplary grid pattern on the back surface of a photovoltaic structure, according to one embodiment of the invention. In the example shown in FIG. 1B, back grid 120 can include three sub-grids, such as sub-grid 122. To enable cascaded and bifacial operation, the back sub-grid may correspond to the front sub-grid. More specifically, the back edge busbar needs to be located near the opposite edge of the front edge busbar. In the examples shown in FIGS. 1A and 1B, the front and back sub-grids have similar patterns except that the front and back edge busbars are located adjacent to opposite edges of the strip. In addition, locations of the blank spaces in back conductive grid 120 correspond to locations of the blank spaces in front conductive grid 102, such that the grid lines do not interfere with the subsequent scribe-and-cleave process. In practice, the finger line patterns on the front and back sides of the photovoltaic structure may be the same or different.

In the examples shown in FIGS. 1A and 1B, the finger line patterns can include continuous, non-broken loops. For example, as shown in FIG. 1A, finger lines 108 and 110 both include connected loops with rounded corners. This type of “looped” finger line pattern can reduce the likelihood of the finger lines peeling away from the photovoltaic structure after a long period of usage. Optionally, the sections where parallel lines are joined can be wider than the rest of the finger lines to provide more durability and prevent peeling. Patterns other than the one shown in FIGS. 1A and 1B, such as un-looped straight lines or loops with different shapes, are also possible.

FIG. 1C shows multiple strips, which are the result of separating a photovoltaic structure along a set of grooves.

The preferred or predetermined depth of the scribed grooves can vary, depending on physical constraints such as the thickness, the intrinsic material properties, and the temperature, etc., of the photovoltaic structure. In general, the groove can be scribed on either side of the photovoltaic structure. In one embodiment, to reduce the likelihood of damage to the interface between the base layer and the emitter layer (i.e., the interface between two semiconductor regions of opposite doping types, also referred to as the “emitter junction”), the groove can be scribed on a side that is opposite to such an interface. Such damage could occur from high temperature if a laser scribing tool is used, or from mechanical forces if other scribing methods are used. In this case, the groove can penetrate, on the side where the surface field layer is located, a transparent conductive oxide (TCO) layer, a heavily doped surface field layer, an optional intrinsic tunneling layer, and a portion of a crystalline Si base layer. The groove depth can be sufficiently large to facilitate precise mechanical cleaving without the laser beam (if laser is used for scribing) reaching the base-layer-to-emitter-layer interface to cause any damage to this interface. As a result, the cleaving action can take place on the side where the groove is. That is, the photovoltaic structure can be held down on the side where the emitter layer is located (i.e., the layer that has a doping type opposite to that of the base layer), and cleaving force can be applied on the side where the surface field layer is located.

The examples described herein are based on the assumption that a photovoltaic structure is cleaved into three strips. Embodiments of the invention, however, are not limited to such a configuration, and can be applied to other cleaving configurations. For example, embodiments of the invention can be used to cleave a photovoltaic structure into two, four, five, six, or more strips in a number of steps.

FIG. 1D shows one example of a groove that can prevent damage to the emitter junction of a photovoltaic structure during a cleaving process. Photovoltaic structure 128 in this example can include N type lightly doped crystalline silicon (c-Si) base layer 130, intrinsic tunneling layer 132, N type heavily doped amorphous silicon (a-Si) surface field layer 134, transparent conductive oxide (TCO) layer 136, and front-side busbar 138. On the back side, the structure can include intrinsic tunneling layer 140, P type a-Si emitter layer 142, TCO layer 144, and back side busbar 146. The back side tunneling junction, formed by P type a-Si emitter layer 142, intrinsic tunneling layer 140, and N type c-Si base layer 130, can transport away the majority carriers generated by base layer 130. The front side tunneling junction, formed by N type heavily doped a-Si surface field layer 134, intrinsic tunneling layer 132, and base layer 130, can transport away the minority carriers generated by base layer 130, thereby reducing the amount of carrier recombination in base layer 130. Tunneling layers 132 and 140 can passivate the interface between base layer 130 and the two heavily doped a-Si layers while still allowing carriers generated by base layer 130 to enter these a-Si layers due to the tunneling effect.

The tunneling junction between base layer 130 and emitter layer 142 is where the majority carriers are removed. It is therefore preferable that the damage caused by scribing and/or cleaving to this interface is kept small. If a laser is used for scribing, the high temperature caused by the laser beam can damage the base-layer-to-emitter junction. Hence, it is desirable to scribe groove 148 on the surface-field-layer side, where groove 148 does not penetrate base layer 130 and reach the base-layer-to-emitter interface. A cleaving process as described herein can be used after the scribing process to attain a clean-cut breakage along the groove. More details of an exemplary photovoltaic structure are provided in U.S. patent application Ser. No. 13/601,441, Attorney Docket No. P53-2NUS, filed Aug. 31, 2012, entitled “BACK JUNCTION SOLAR CELL WITH TUNNEL OXIDE,” the disclosure of which is hereby incorporated by reference in its entirety herein.

Exemplary photovoltaic structure 128 shown in FIG. 1D includes an N type lightly doped c-Si base layer. In general, the base layer can be either N or P type doped, or undoped, and can be made of a variety of materials, including c-Si, a-Si, poly-crystalline silicon, or non-silicon materials. Various device structures and designs based on different materials can also be used to construct the photovoltaic structure. For example, the photovoltaic structure can be a wafer-based photovoltaic structure, or a thin film photovoltaic structure, which might have a size and shape different from those of regular wafers. Preferred embodiments of the present invention provide a system that can cleave a photovoltaic structure along a groove to produce multiple strips without damaging the interface between the base layer and emitter layer of the strips.

For example, for a typical crystalline-Si-based photovoltaic structure with a stack thickness ranging from 200 to 700 microns, the groove depth can range from 5 to 100 microns. Preferably, the groove depth can be up to 30 or 50 microns. In one embodiment, the depth of the groove can be approximately 20 microns. For thin-film-based photovoltaic structures with a smaller stack thickness, the groove depth can be reduced correspondingly. Alternatively, the groove depth can be measured as a percentage of the thickness of the photovoltaic structure. The depth of the groove can be, for example, up to 70% of the thickness of the photovoltaic structure. In one embodiment, the depth of the groove can be 2%-70% of the thickness of the photovoltaic structure. In a further embodiment, the groove depth can be 10%-40% of the structure's thickness. Preferably, the groove depth can be approximately 20% of the structure's thickness.

In some embodiments, an automatic scribing tool is used to scribe one or more grooves (e.g., groove 148) on photovoltaic structures. More details of the automatic scribing tool can be found in U.S. patent application Ser. No. 14/804,306, Attorney Docket No. P103-SNUS, filed Jul. 20, 2015, entitled “SYSTEMS AND METHODS FOR SCRIBING PHOTOVOLTAIC STRUCTURES,” the disclosure of which is hereby incorporated by reference in its entirety herein.

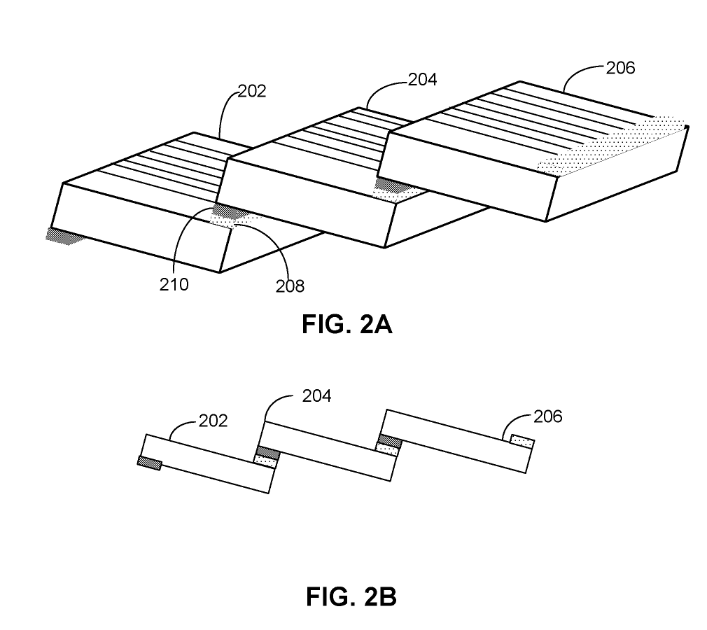

To form a cascaded string, cells or strips (e.g., as a result of a scribing and cleaving process applied to a regular square-shaped cell) can be cascaded with their edges overlapped. FIG. 2A shows a string of cascaded strips, according to an embodiment of the invention. In FIG. 2A, strips 202, 204, and 206 are stacked in such a way that strip 206 partially overlaps adjacent strip 204, which also partially overlaps (on an opposite edge) strip 202. Such a string of strips forms a pattern that is similar to that of roof shingles. Each strip includes top and bottom edge busbars located at opposite edges of the top and bottom surfaces, respectively. Strips 202 and 204 are coupled to each other via an edge busbar 208 located at the top surface of strip 202 and an edge busbar 210 located at the bottom surface of strip 204. To establish electrical coupling, strips 202 and 204 are placed in such a way that bottom edge busbar 210 is placed on top of and in direct contact with top edge busbar 208.

FIG. 2B shows a side view of the string of cascaded strips, according to one embodiment of the invention. In the example shown in FIGS. 2A and 2B, the strips can be part of a 6-inch square-shaped photovoltaic structure, with each strip having a dimension of approximately 2 inches by 6 inches. To reduce shading, the overlapping between adjacent strips should be kept as small as possible. In some embodiments, the single busbars (both at the top and the bottom surfaces) are placed at the very edge of the strip (as shown in FIGS. 2A and 2B). The same cascaded pattern can extend along an entire row of strips to form a serially connected string.

From FIGS. 2A and 2B one can see that, other than at both ends of a string, all busbars are sandwiched between the overlapped strips. This no-busbar configuration reduces shading.

### Automatic Cleaving System

To meet the precision and throughput requirements of the solar panel assembly line, an automatic tool that can divide the scribed wafers into smaller strips is needed. However, existing cleaving tools often require that the photovoltaic structures be positioned precisely during cleaving, and misalignment can often lead to unsuccessful cleaving or cause damage to the photovoltaic structure. An automatic cleaving tool that is more tolerant to the misalignment of the photovoltaic structure is desired.

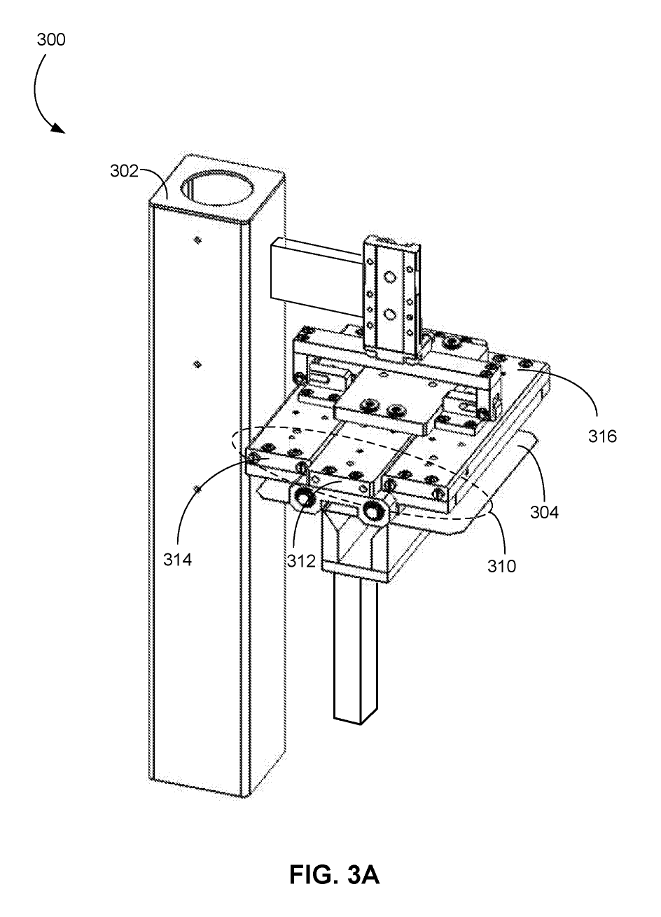

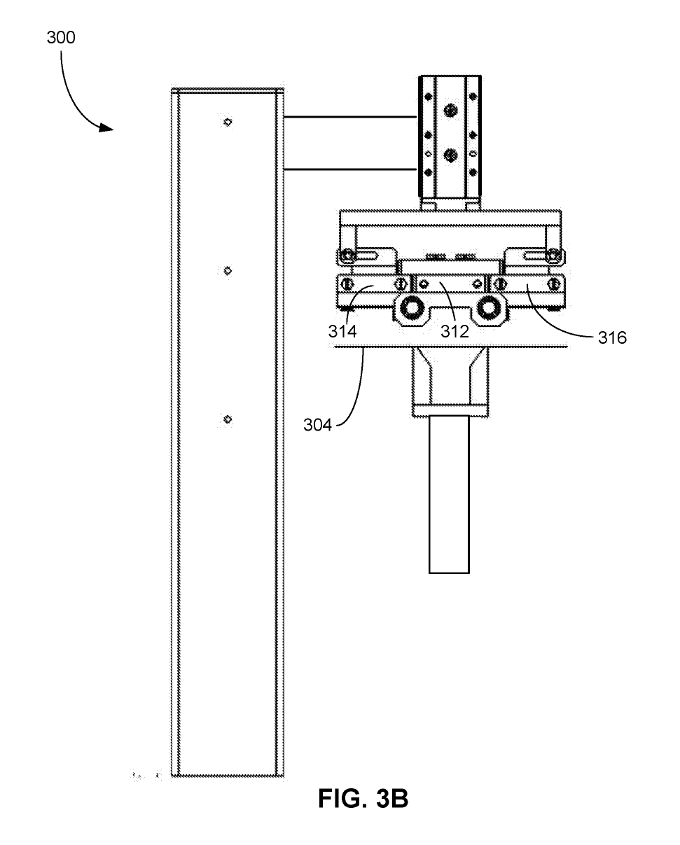

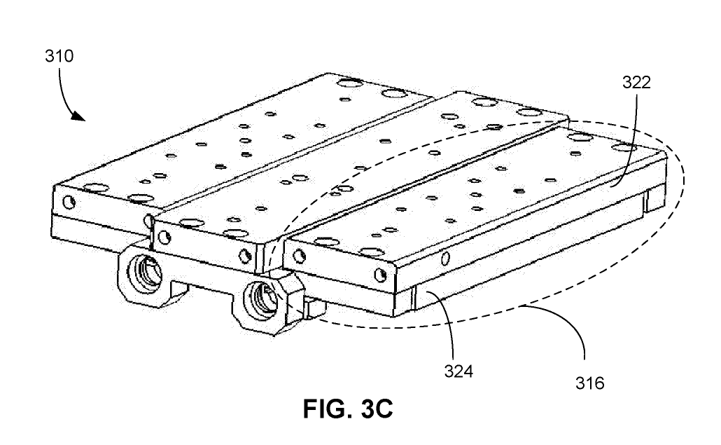

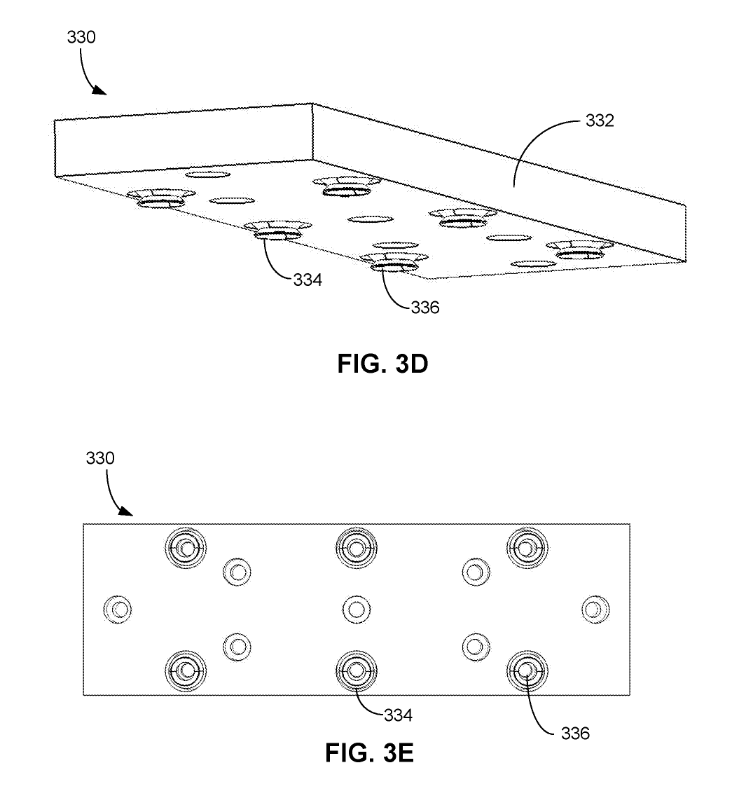

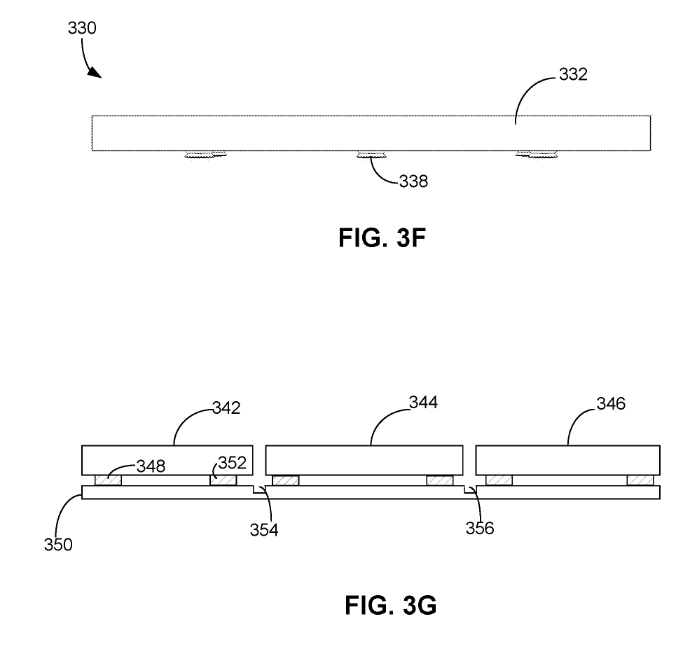

In some embodiments, an automatic cleaving tool that can break a photovoltaic structure along a scribed line without requiring precise placement of the photovoltaic structure is provided. FIG. 3A illustrates the perspective view of an exemplary cleaving system, according to one embodiment.

Cleaving system 300 can include stationary post 302 and cleaving platform 310 attached to post 302. In some embodiments, stationary post 302 can support the entire cleaving system and can be attached to an external frame or the factory floor. Cleaving platform 310 can be attached to stationary post 302 via a translation stage, which allows cleaving platform 310 to move in the vertical direction. In some embodiments, cleaving platform 310 can include a wafer-picking-up-and-holding mechanism for picking up a wafer or photovoltaic structure 304 from a conveyor and holding it in midair. Cleaving platform 310 can also be segmented, including separate segments that can move relative to each other. The relative movements of the separate segments of cleaving platform 310 can result in wafer or photovoltaic structure 304 being cleaved into multiple strips.

In the example shown in FIG. 3A, cleaving platform 310 can include a stationary center segment 312 and two movable side segments 314 and 316. Wafer 304 can include two scribed grooves, and wafer 304 can be positioned in such a way that, when the wafer-picking-up-and-holding mechanism picks up wafer 304, each of the two grooves is roughly aligned with and positioned beneath a corresponding gap separating center segment 312 and a side segment. In some embodiments, when two movable side segments 314 and 316 rotate around the corresponding edge of center segment 312, wafer 304 breaks along the two scribed grooves into three separate strips.

In FIG. 3A, cleaving platform 310 is configured in the “open” position. For better viewing effect, FIG. 3B shows the side view of the exemplary cleaving system with the cleaving platform configured in the “open” position, according to one embodiment. As shown in FIG. 3B, when the cleaving platform is in the open position, side segments 314 and 316 are aligned with center segment 312, with their bottom surfaces on the same horizontal plane. During operation, the cleaving platform can be lowered to pick up to-be-cleaved wafer 304 from a wafer-carrying surface, such as a conveyor (not shown in FIGS. 3A-3B). More specifically, the bottom of cleaving platform 310 can include a number of vacuum cups that can pick up to-be-cleaved wafer 304 from the conveyor using vacuum forces.

FIG. 3C shows an amplified view of the cleaving platform, according to one embodiment. From FIG. 3C, one can see that each of the three segments of cleaving platform 310 can actually include two portions, a top portion and a bottom portion. For example, side segment 316 can include a top portion 322 and a bottom portion 324. The top portion of each segment of platform 310 can act as a coupling base for coupling the corresponding segment to other parts of the cleaving system. In some embodiments, the top portion of the center segment can be coupled to a translation stage (not shown in FIG. 3C), which is coupled to the stationary post. The translation stage can enable linear (e.g., along the vertical direction) motion of cleaving platform 310. Movements of the translation stage can be automatically controlled. Different actuating mechanisms can be used to drive the translation stage, including but not limited to: a stepper motor, a servo motor, a DC motor with an encoder, a piezoelectric motor, a hydraulic motor, and a pneumatic motor. In one embodiment, a pneumatic-based actuator can be used to vertically move cleaving platform 310. The bottom portion of each segment of platform 310 can include vacuum cups used for picking up and holding the wafer.

FIG. 3D shows an amplified view of the bottom portion of a platform segment, according to an embodiment. Bottom portion 330 can include metallic (e.g., stainless steel) base 332 and a number of vacuum cups, such as vacuum cups 334 and 336, embedded inside metallic base 332. In the example shown in FIG. 3D, bottom portion 330 includes up six vacuum cups arranged in a two-by-three array. The vacuum cups can be made of soft material (e.g., rubber or plastic) to prevent damage to the wafers. FIG. 3E shows the bottom view of bottom portion 330, according to an embodiment. FIG. 3E shows that the vacuum cups are positioned near the longer edge of the platform segment and are arranged in a two-by-three array. FIG. 3F shows the side view of bottom portion 330, according to an embodiment. In FIG. 3F, the vacuum cups (e.g., vacuum cup 338) are shown to be extruding from base 332. This can prevent direct contact between the wafer and base 332, thus reducing possible contamination caused by debris generated during cleaving.

FIG. 3G shows the placement of a to-be-cleaved wafer with respect to the cleaving platform, according to one embodiment. In FIG. 3G, the different segments of the cleaving platform (e.g., segments 342, 344, and 346) each can include multiple vacuum cups for holding to-be-cleaved wafer 350. For example, platform segment 342 can include vacuum cups 348 and 352. Adjacent platform segments can be separated from each other by an air gap ranging between 0.5 and 10 mm. Wafer 350 can include a number of scribed grooves (e.g., grooves 354 and 356) positioned on the side that faces the cleaving platform. To enable subsequent cleaving, wafer 350 can be arranged in such a way that each scribed groove is substantially parallel to and positioned below a gap separating adjacent platform segments. For example, groove 354 is substantially parallel to and positioned below the gap separating platform segments 342 and 344. Similarly, groove 356 is substantially parallel to and positioned below the gap separating platform segments 344 and 346. This arrangement ensures that relative movements between adjacent platform segments can result in wafer 350 being cleaved along scribed grooves. However, the alignment between a groove and a gap does not need to be very precise. Because the vacuum cups holding wafer 350 are positioned near but not exactly on the edge of each platform segment, slight misalignment between the grooves and the gaps does not lead to failed cleaving.

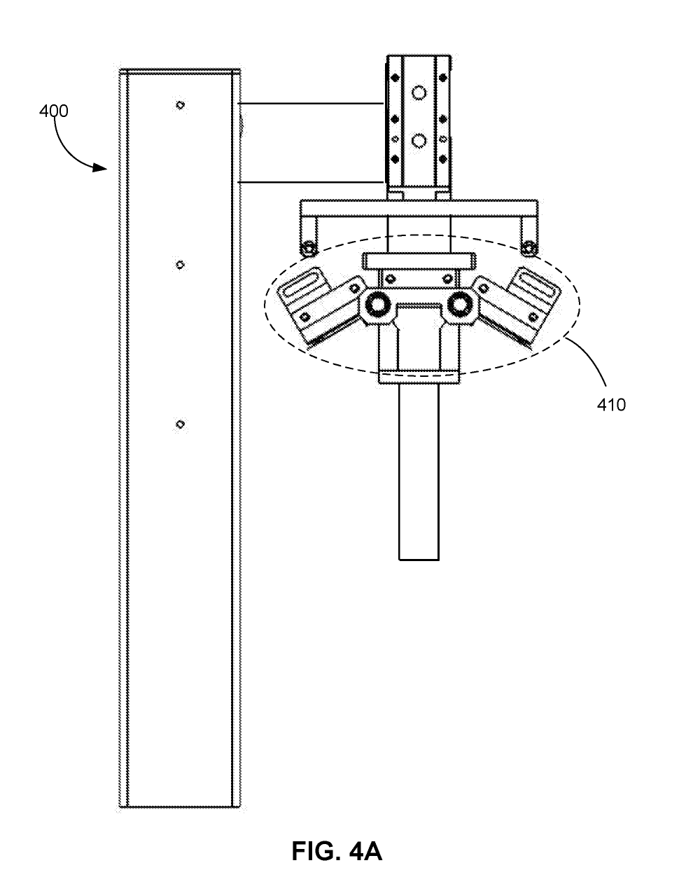

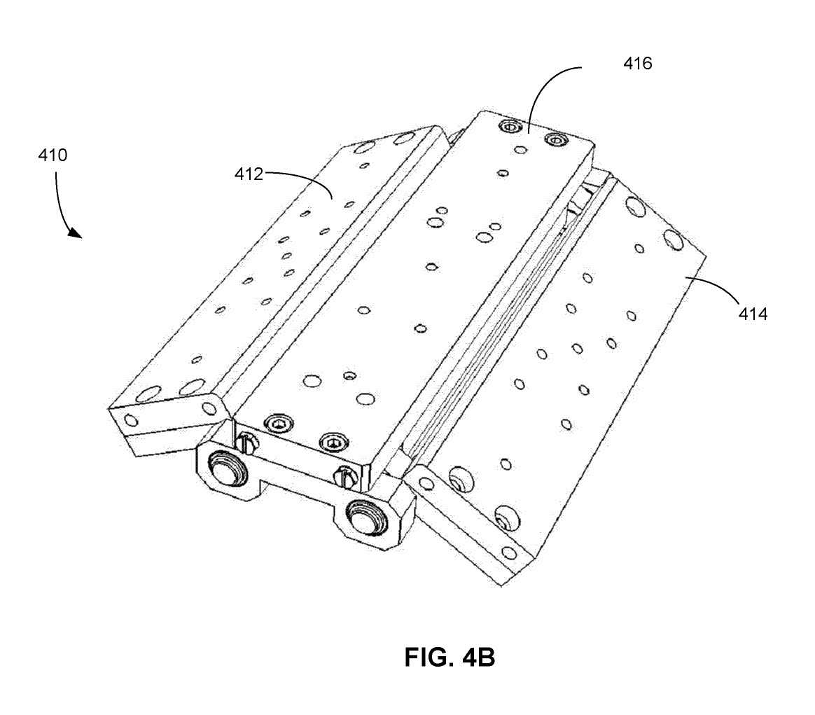

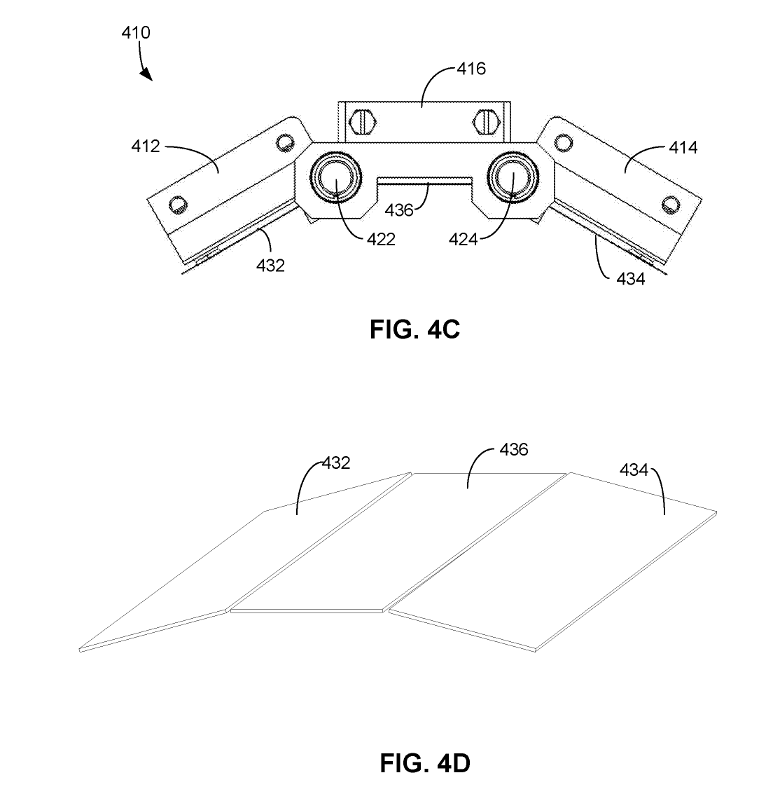

After picking up a wafer, the cleaving system can perform the cleaving operation in midair, breaking the wafer into multiple smaller strips. In some embodiments, the cleaving system can break the wafer by rotating, downward, the two movable side segments of the cleaving platform. FIG. 4A illustrates the side view of the exemplary cleaving system with the cleaving platform configured in the “closed” position, according to one embodiment.

In FIG. 4A, cleaving platform 410 of cleaving system 400 is configured in the “closed” position, with the two movable side segments each forming an angle with the horizontally positioned center segment. In some embodiments, cleaving platform 410 can be closed by rotating both side segments downward from their original horizontal position. If cleaving platform 410 is holding a wafer in midair, the rotation of the two side segments can assert stress along scribed grooves on the wafer surface, cleaving the wafer into three strips.

FIG. 4B shows an amplified view of the cleaving platform in the closed position, according to one embodiment. In FIG. 4B, side segments 412 and 414 of cleaving platform 410 are folded downward toward center segment 416. FIG. 4C shows the side view of the cleaving platform in the closed position, according to one embodiment. In FIG. 4C, side segments 412 and 414 are shown to be hinged to center segment 416 via axes 422 and 424, respectively. During operation, side segments 412 and 414 can rotate around axes 422 and 424, respectively. The rotation of side segments 412 and 414 can cleave a wafer into three strips (e.g., strips 432, 434, and 436), with each strip attached to a corresponding segment of the cleaving platform via vacuum cups. For example, strips 432 and 434 are attached to side segments 412 and 414, respectively, and strip 436 is attached to center segment 416. FIG. 4D shows the perspective view of the wafer strips, according to one embodiment.

In some embodiments, after cleaving, the two side segments of the cleaving platform can rotate upward, back to their horizontal position while continuing to hold the wafer strips. Subsequently, the entire cleaving platform can be lowered to release the wafer strips onto the conveyor.

An actuation mechanism is needed to rotate the side segments of the cleaving platform. In some embodiments, instead of using two separate actuators to move the two side segments, a single actuator along with a specially designed motion-transmission system (e.g., a cam-follower mechanism) can be used to move the two side segments simultaneously.

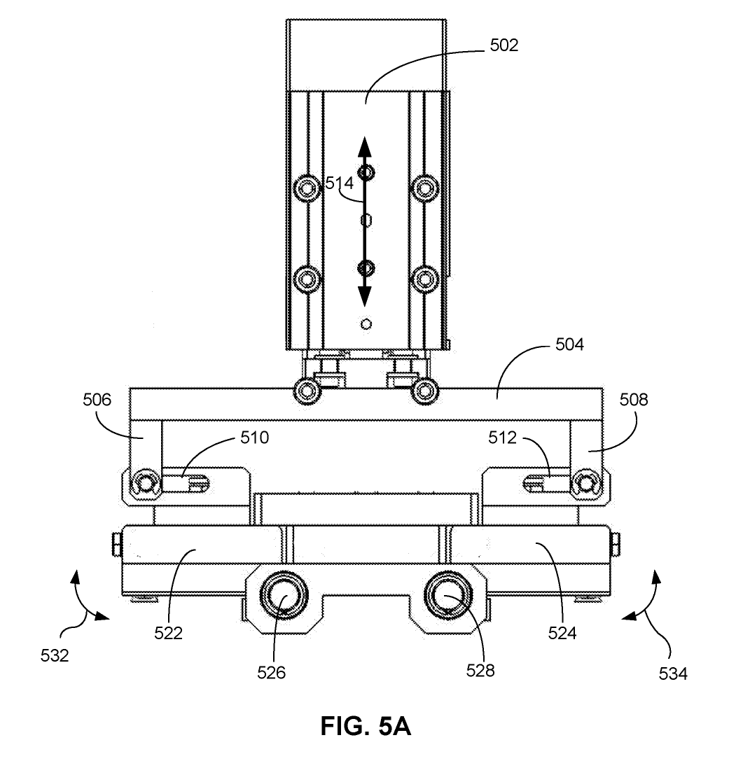

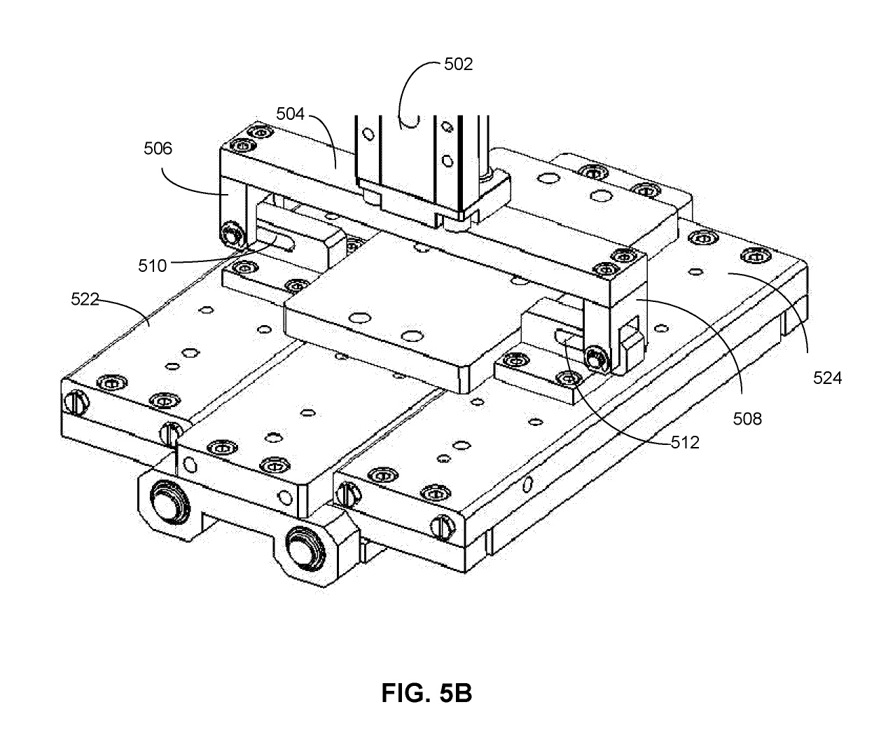

FIG. 5A shows the side view of the cleaving platform along with the actuator and motion transmission system, according to one embodiment. Actuator 502 is capable of vertical movements and coupled to a rigid horizontal beam 504. In some embodiments, actuator 502 can include a pneumatic-based actuator. Other types of actuating mechanism are also possible, including but not limited to: stepper-motor based actuators or piezoelectric actuators. The vertical movements of actuator 502 can result in vertical movements of horizontal beam 504 and cams 506 and 508. Cams 506 and 508 are attached to both ends of horizontal beam 504 and move along with horizontal beam 504. FIG. 5A shows that the upper ends of cams 506 and 508 are attached to horizontal beam 504 and the lower ends of cams 506 and 508 are confined in pre-defined slots 510 and 512, respectively. Due to such confinements, the vertical movements (as shown by double arrow 514) of actuator 502 can cause cams 506 and 508 to slide within slots 510 and 512, respectively. Because slots 510 and 512 are rigidly attached to moveable side segments 522 and 524, respectively, and side segments 522 and 524 are freely hinged to the center segment of the cleaving platform via axes 526 and 528, respectively, vertical movements of cams 506 and 508 can be converted to rotations of side segments 522 and 524, as indicated by double arrows 532 and 534, respectively.

FIG. 5B shows the perspective view of the cleaving platform along with the actuator and motion transmission system, according to one embodiment.

In FIG. 5B, pre-defined slots 510 and 512 are shown to be bolted onto side segments 522 and 524, respectively, with the tracks running parallel to the shorter edge of each side segment. Other coupling mechanisms can also be possible to attached pre-defined slots 510 and 512 to the side segments. The dimensions of horizontal beam 504 and cams 506 and 508 can be designed in such a way that when actuator 502 is at its highest position, cams 506 and 508 can move to the outmost edges of slots 510 and 512, respectively, horizontally aligning side segments 522 and 524 with the center segment.

In addition to having three separate segments as shown in FIGS. 3A-5B, the cleaving platform may have other configurations, depending on the cleaving need. For example, to cleave a wafer or photovoltaic structure into two strips, the cleaving platform may have two separate segments, one stationary and the other movable. It is also possible for both segments to be movable. In such a scenario, the two movable segments can rotate around a common axis, cleaving the wafer into two strips.

In the example shown in FIGS. 3A-5B, the shape of the bottom surface of the cleaving platform substantially matches the shape of the to-be-cleaved wafer. In practice, it is also possible for the bottom surface to have different shapes, such as a circle or an oval. Regardless of its shape, the cleaving platform will be able to perform the cleaving operation as long as the cleaving forces resulting from the relative movements of the different segments are applied at locations substantially near the scribed groove or grooves. Ideally, the rotation axis of the relative movements between adjacent segments should be substantially parallel to the scribed groove.

Other variations can also be possible. For example, other than holding the wafer in midair below the cleaving platform using suction cups, it is also possible to hold the wafer above the cleaving platform using suction cups or vacuum holes. In such a scenario, the grooves will be on the backside of the wafer, facing the cleaving platform, and the two side segments of the cleaving platform may rotate upward in order to cleave the wafer.

In addition to the cleaving platform that holds the to-be-cleaved wafer from one side (e.g., the top) of the wafer, in some embodiments, the cleaving system can also include a supporting mechanism that supports the center portion of the to-be-cleaved wafer from the other side (e.g., the bottom) of the wafer. This way, during cleaving, while the side portions of the to-be-cleaved wafer are experiencing a downward pressure caused by the rotation of the two side segments of the cleaving platform, the center portion of the to-be-cleaved wafer is experiencing an upward force provided by the supporting mechanism. These two opposing forces can cause the wafer to be cleaved along the scribed grooves. If the to-be-cleaved wafer is held on top of the cleaving platform with its bottom surface supported by the cleaving platform, a counterforce-applying mechanism that can apply a downward force to the top surface of the wafer can be used instead of the supporting mechanism.

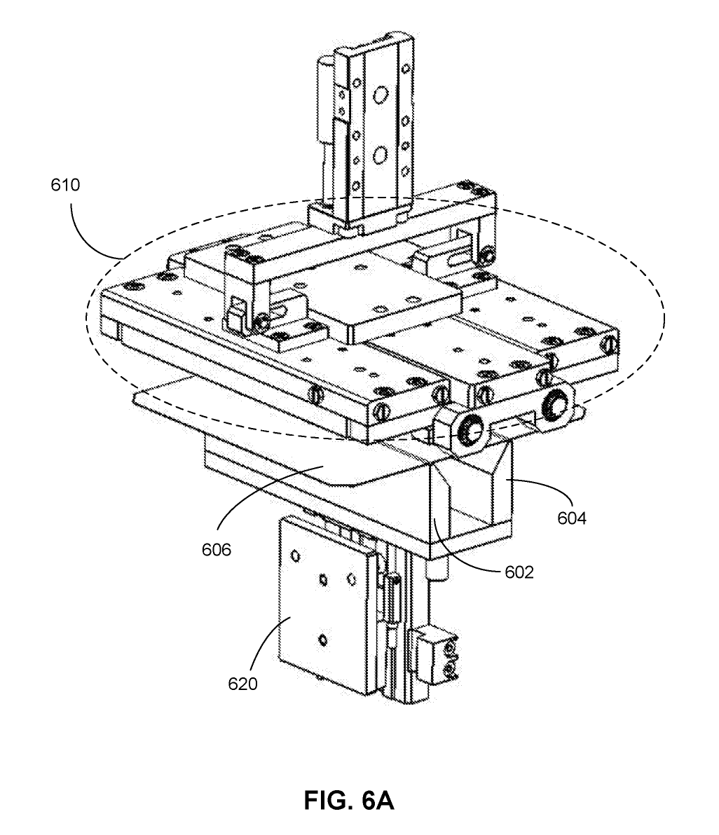

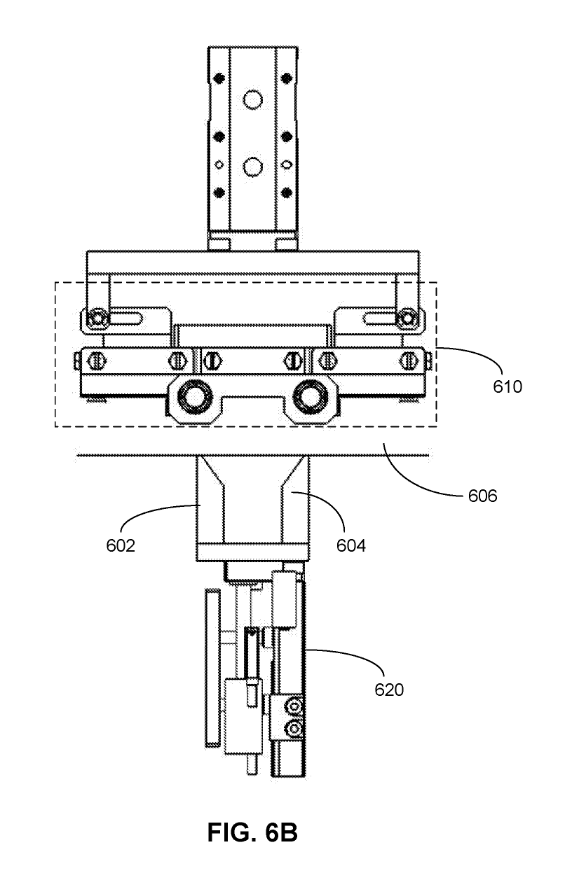

FIG. 6A shows the supporting mechanism positioned below the cleaving platform, according to one embodiment. FIG. 6B shows the side view of the supporting mechanism positioned below the cleaving platform, according to one embodiment. The supporting mechanism can include two separate ridges, ridges 602 and 604. The top edges of the ridges are positioned below to-be-cleaved wafer 606 and cleaving platform 610. FIGS. 6A-6B show that, before wafer 606 is picked up by cleaving platform 610, wafer 606 can be supported by ridges 602 and 604. Ridges 602 and 604 are coupled to translation stage 620, which can move ridges 602 and 604 in the vertical direction.

The cleaving operation can start with cleaving platform 610 picking up wafer 606. Subsequently, translation stage 620 can move ridges 602 and 604 upward to come into contact with wafer 606. While wafer 606 is sandwiched between cleaving platform 610 and ridges 602 and 604, the side segments of cleaving platform 610 can rotate downward, cleaving wafer 606 into three strips.

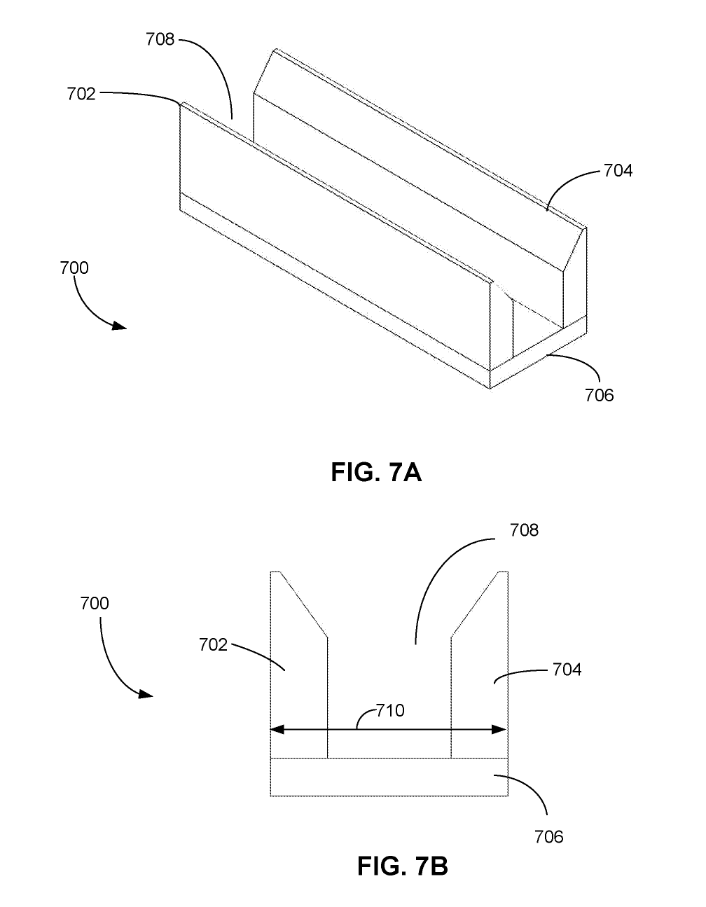

FIG. 7A shows the perspective view of the supporting mechanism, according to one embodiment. FIG. 7B shows the side view of the supporting mechanism, according to one embodiment. In the example shown in FIGS. 7A and 7B, supporting mechanism 700 can include ridges 702 and 704 positioned on base 706 and separated from each other by gap 708.

In the example shown in FIGS. 7A-7B, each of the ridges can have a narrower top and a wider bottom. For example, a ridge can be obtained by truncating a rectangular prism. During cleaving, the narrow top surface of a ridge can be in direct contact with the to-be-cleaved wafer, asserting an upward force onto the wafer. In some embodiments, the distance between the outer edges of ridges 702 and 704 (as indicated by arrow 710) is less than the distance between the two scribed grooves, and the wafer can be placed on top of supporting mechanism 700 in such a way that both ridges are located between the scribed grooves. This design can allow the upward force provided by the ridges and the downward force caused by the rotation of the side segments to be applied on opposite sides of the scribed grooves, thus increasing the cleaving effect. The narrow area of contact between the wafer and supporting mechanism 700 can ensure that the upward force is applied locally, at a location near the scribed grooves.

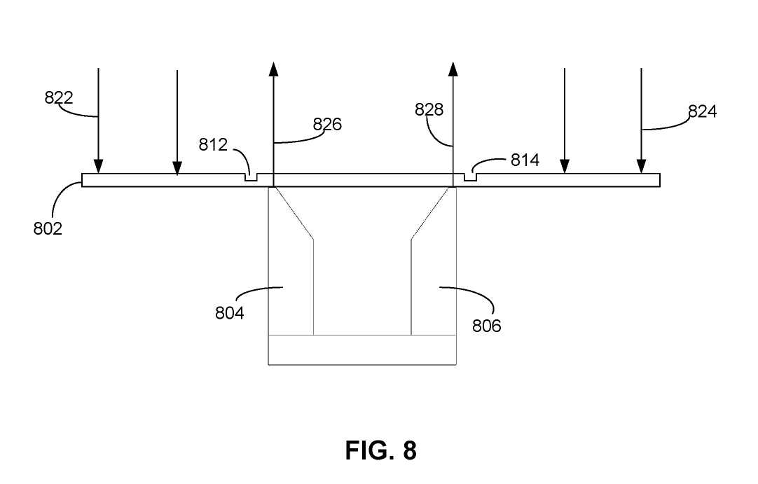

FIG. 8 shows the opposing forces applied to a wafer during cleaving, according to one embodiment. In FIG. 8, wafer 802 is supported by ridges 804 and 806. Wafer 802 includes two scribed grooves, grooves 812 and 814. As disclosed previously, wafer 802 is placed in such a way that ridges 804 and 806 are positioned between grooves 812 and 814. The downward pointed arrows (e.g., arrows 822 and 824) represent the downward forces applied to wafer 802. In some embodiments, these downward forces are generated by the downward rotation of the side segments of the cleaving platform. The upward pointed arrows (e.g., arrows 826 and 828) represent the upward forces applied to wafer 802 by ridges 804 and 806, in reaction to the downward forces. These opposing forces are applied on opposite sides of a groove, thus leading to successful cleaving of wafer 802 along the scribed grooves. From FIG. 8, one can see that there is no well-defined fulcrum for the forces. This means that the wafer does not need to be aligned precisely with respect to the cleaving platform and the supporting ridges, thus making the cleaving system more tolerant to misalignments of the wafer.

In addition to the ridges shown in FIGS. 7A-7B, the supporting mechanism may have other shapes and sizes, as long as the outer edges of the supporting mechanism are located between the scribed grooves when supporting the to-be-scribed wafer. For example, the supporting mechanism may be shaped like a rectangular prism, or each ridge may be shaped like a rectangular prism.

The cleaving system that has been shown so far does not include a wafer-transfer system, and the wafer can be manually placed onto the supporting mechanism before it is cleaved. In practice, to increase its throughput, the cleaving system can include a conveyor system for transportation of wafers. For example, the conveyor system can transport a to-be-cleaved wafer to a location beneath the cleaving platform and then pause to allow the wafer to be picked up and cleaved by the cleaving platform. After cleaving, the separate strips of the cleaved wafer can be placed back on the conveyor system to be transported to the next processing station.

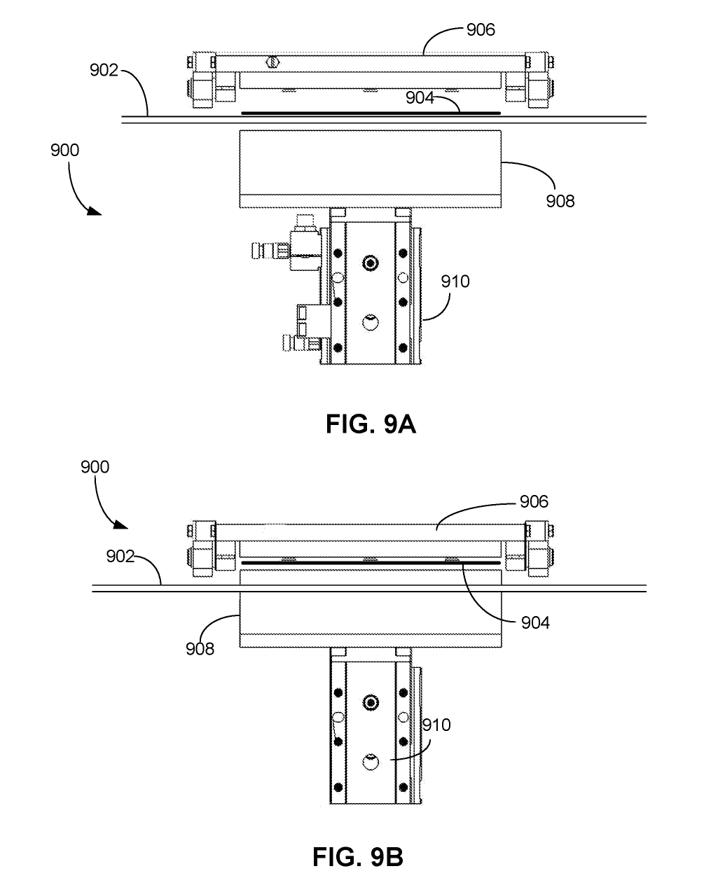

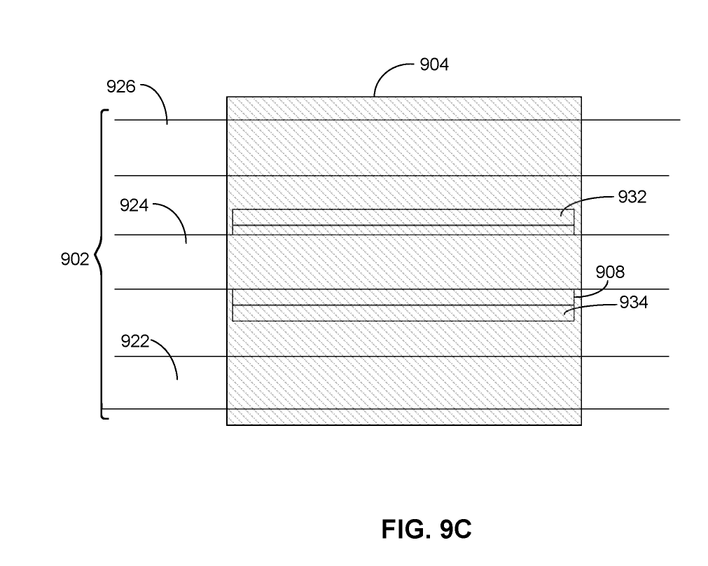

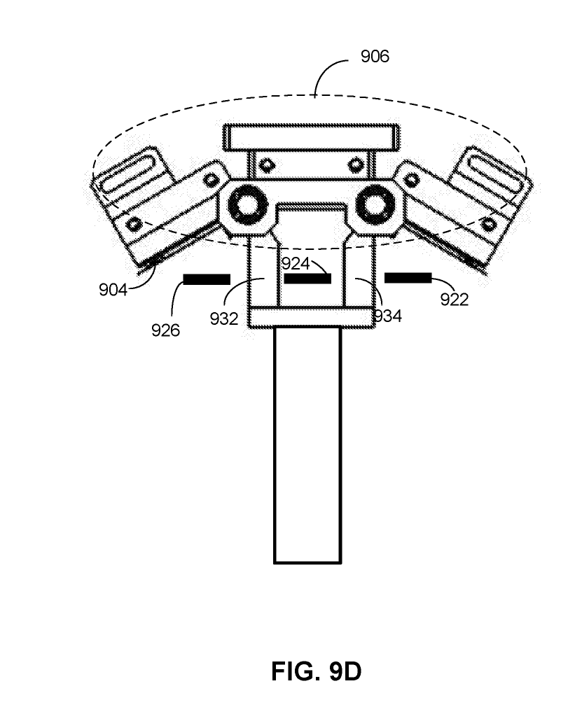

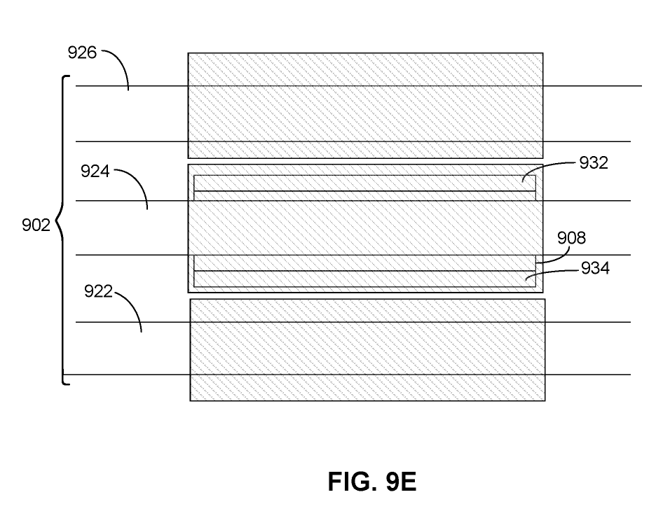

In some embodiments, the supporting mechanism (e.g., the supporting ridges shown in FIGS. 7A-7B) can be positioned below the conveyor system before cleaving and can be elevated during the cleaving operation to make contact with and provide support to the wafer. FIG. 9A shows the partial front view of a cleaving system incorporating a conveyor before cleaving, according to one embodiment. Cleaving system 900 can include conveyor 902 for transporting wafers (e.g., wafer 904), cleaving platform 906, and supporting mechanism 908. In FIG. 9A, wafer 904 can be carried by conveyor 902 from a previous processing station to a location directly underneath cleaving platform 906. Supporting mechanism 908 is located beneath both cleaving platform 906 and conveyor 902. In some embodiments, conveyor 902 pauses after carrying wafer 904 to the location directly underneath cleaving platform 906.

FIG. 9B shows the partial front view of the cleaving system incorporating a conveyor during cleaving, according to one embodiment. In FIG. 9B, cleaving platform 906 has picked up (e.g., using suction cups) wafer 904 from conveyor 902. To assist cleaving, supporting mechanism 908 can move up, partially passing through conveyor 902 to be in contact with the back side of wafer 904. For a better viewing effect, FIG. 9B shows a small gap between supporting mechanism 908 and wafer 904. In practice, supporting mechanism 908 moves up until it is in contact with wafer 904. In some embodiments, a translation stage (e.g., translation stage 910) coupled to supporting mechanism 908 can be used to raise supporting mechanism 908. The travel distance of supporting mechanism 908 can be carefully controlled by the controller of translation stage 910. Similar to other linear stages used in the cleaving system, translation stage 910 can be driven by a pneumatic-based actuator.

FIG. 9C shows the top view of the conveyor and supporting mechanism, according to one embodiment. Conveyor 902 can include a number of belts, such as belts 922, 924, and 926, separated from each other by an air gap. The gap can be much smaller than the width of to-be-cleaved wafers (e.g., wafer 904) to ensure that the wafers can be safely carried by conveyor 902. FIG. 9C also shows that the two ridges of supporting mechanism 908 (e.g., ridges 932 and 934) can be positioned between the belts of conveyor 902. For example, ridge 932 is positioned between belts 924 and 926, and ridge 934 is positioned between belts 922 and 924. This way, after wafer 904 has been picked up by the cleaving platform, ridges 932 and 934 can move upward, passing conveyor 902 through the gaps between the belts, to come into contact with wafer 904.

FIG. 9D shows the partial side view of the cleaving system incorporating a conveyor after cleaving, according to one embodiment. In FIG. 9D, the two side segments of cleaving platform 906 have rotated downward, cleaving wafer 904 into three strips. FIG. 9D also shows ridges 932 and 934 passing belts 926, 924, and 922 though the gaps between the belts.

After the cleaving operation, the side segments of cleaving platform 906 can rotate back to their horizontal positions, the supporting mechanism can return back to its location below the conveyor, and the cleaving platform can be lowered to release and place the strips back onto the conveyor. The conveyor can then resume movement to transport the strips to the next processing station and bring a next to-be-cleaved wafer to the location beneath the cleaving platform. FIG. 9E shows the strips of the cleaved wafer placed on the conveyor, according to one embodiment.

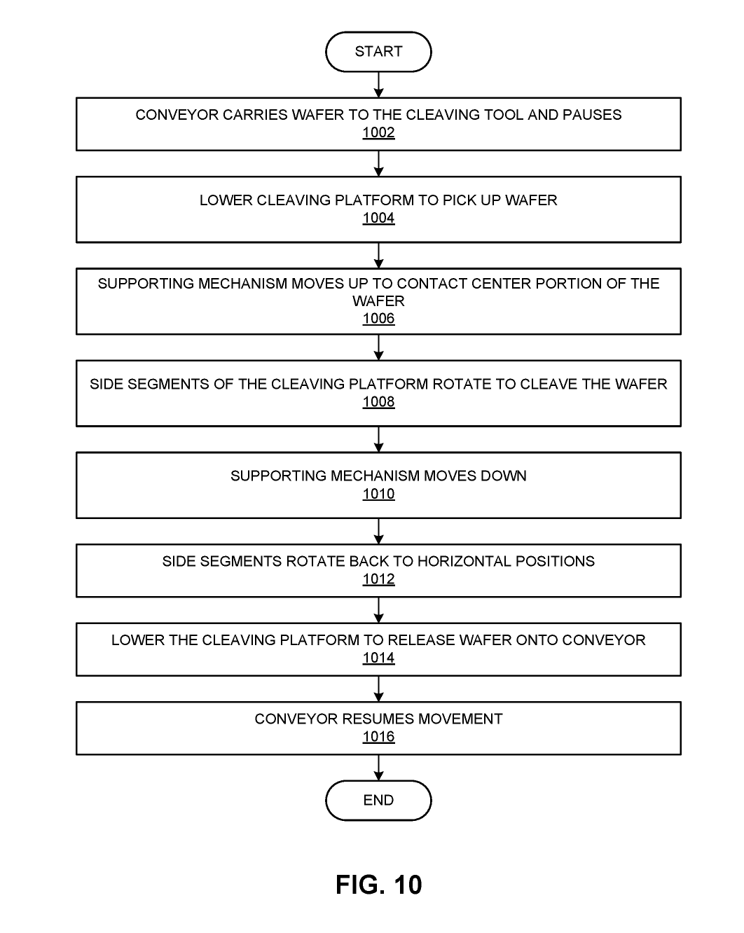

FIG. 10 presents a flowchart illustrating the cleaving process, according to one embodiment. During operation, the conveyor carries a to-be-cleaved wafer to the automatic cleaving tool and pauses (operation 1002). The cleaving platform of the automatic cleaving tool can be lowered and the vacuum of the vacuum cups embedded in the cleaving platform can be turned on to pick up the to-be-cleaved wafer (operation 1004). In some embodiments, the cleaving platform can be coupled to a supporting post via a linear stage and vertical (up and down) movements of the cleaving platform can be driven by different types of actuators, including but not limited to: a stepper motor, a servo motor, a DC motor with an encoder, a piezoelectric motor, a hydraulic motor, and a pneumatic motor. The timing and distance of the movements of the cleaving platform can be automatically controlled by a controller to sync the cleaving operation with the conveyor movements.

Subsequent to the cleaving platform picking up the to-be-cleaved wafer, the supporting mechanism can move upward from a location below the conveyor to come into contact with the back side of the to-be-cleaved wafer (operation 1006). More specifically, the supporting mechanism can provide upward support to the center portion of the to-be-cleaved wafer. The supporting mechanism can be coupled to the same supporting post supporting the cleaving platform or to other stationary components of the cleaving system. In some embodiments, movements of the supporting mechanism can be driven by different types of actuators, including but not limited to: a stepper motor, a servo motor, a DC motor with an encoder, a piezoelectric motor, a hydraulic motor, and a pneumatic motor. This operation can be optional. In some embodiments, the wafer may be cleaved without its center portion being supported.

Once the supporting mechanism is in position, the two movable side segments of the cleaving platform can rotated about the edges of the stationary center segment, cleaving the wafer into three separate strips (operation 1008). In some embodiments, rotating the two movable side segments can involve a single vertical actuator and a specially designed cam-follower system. More specifically, the downward movements of two cams driven by a vertical actuator can be converted to the rotation of the two side segments Like other actuators used in the system, the vertical actuator for moving the two side segments can be driven by different types of motors, including but not limited to: a stepper motor, a servo motor, a DC motor with an encoder, a piezoelectric motor, a hydraulic motor, and a pneumatic motor.

After the wafer is cleaved, the supporting mechanism can move down to return to its resting position below the conveyor (operation 1010), and the two side segments can rotate back to their original horizontal positions (operation 1012). The rotation of the two side segments can result from the vertical actuator lifting up the two cams.

Subsequently, the cleaving platform can be lowered to place strips of the cleaved wafer onto the conveyor (operation 1014). In some embodiments, to release the cleaved wafer, the vacuum for the vacuum cups is turned off and optionally air or nitrogen streams can be propelled out of the vacuum cups to gently “blow” off the strips. Note that this wafer-releasing method prevents possible accumulation of debris on the vacuum cups, thus reducing contamination. After the strips have been placed onto the conveyor, the conveyor resumes movement (operation 1016).

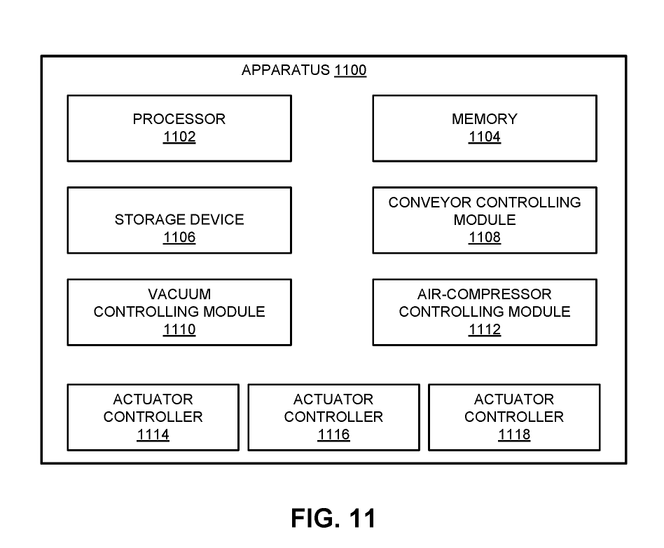

FIG. 11 shows an exemplary controlling apparatus that can facilitate cleaving a photovoltaic structure into multiple strips, according to one embodiment. Apparatus 1100 can include a plurality of modules that may communicate with one another via a wired or wireless communication channel. Apparatus 1100 may be realized using one or more integrated circuits, and may include fewer or more modules than those shown in FIG. 11. Further, apparatus 1100 may be integrated in a computer system, or realized as a separate device that is capable of communicating with other computer systems and/or devices.

Controlling apparatus 1100 can include processor 1102, memory 1104, and storage device 1106. Memory 1104 can include a volatile memory (e.g., RAM) that serves as a managed memory, and can be used to store one or more memory pools. In some embodiments, storage device 1106 can store an operating system, and instructions for monitoring and controlling the cleaving process.

Apparatus 1100 can also include conveyor controlling module 1108, vacuum controlling module 1110, air-compressor controlling module 1112, and a number of actuator controlling modules (e.g., actuator controllers 1114, 1116, and 1118). Conveyor controlling module 1108 can control the movement of the conveyor to move photovoltaic structures to the cleaving tool, and can move the cleaved strips away from the cleaving tool. Vacuum controlling module 1110 can control a vacuum pump that may apply a suction force to a plurality of vacuum cups embedded in the cleaving platform, and air-compressor controlling module 1112 can control an air compressor that may propel air streams out of the vacuum cups. Actuator controllers 1114, 1116, and 1118 can each control a pneumatic pump, hydraulic pump, or servo motor to control the movements of the various linear stages included in the cleaving system. The activation times of the actuators are coordinated with respect to each other and the conveyor movements.

### Solar Module Assembly Line

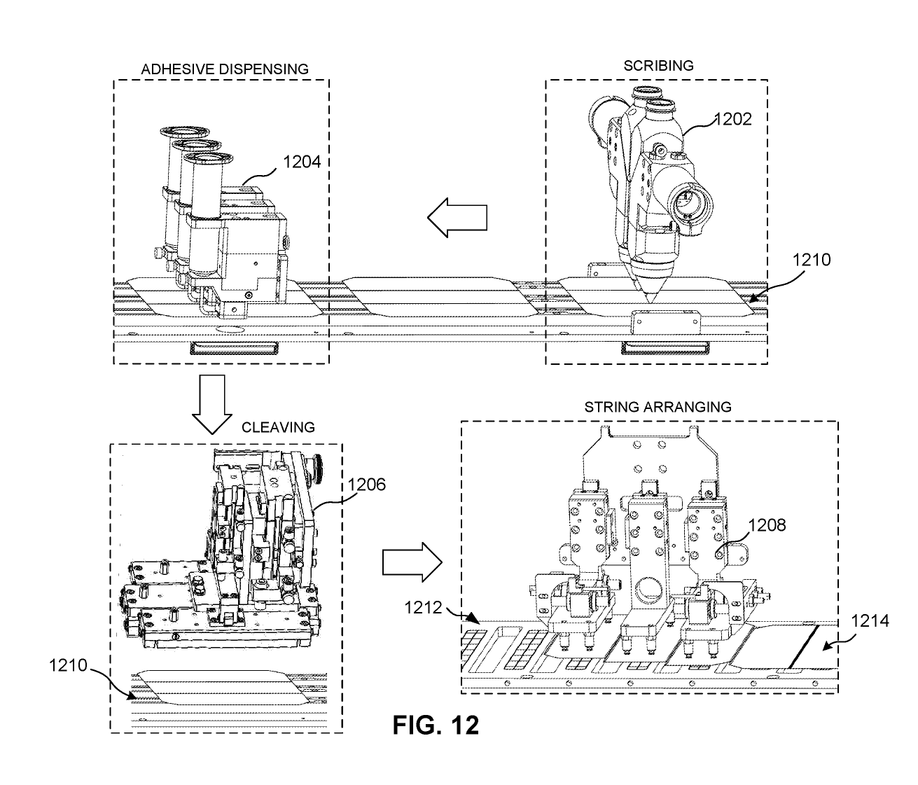

FIG. 12 shows a sequence of steps for processing photovoltaic structures to produce a string, according to one embodiment. In this example, conveyor 1210 can move photovoltaic structures to scribing system 1202, which can scribe one or more grooves along the busbars of each photovoltaic structure. Conveyor 1210 can then move the photovoltaic structures to adhesive-dispensing system 1204, which can dispense a conductive adhesive paste on busbars of the strips, so that after cleaving these strips can be bonded together in a cascaded arrangement.

After application of the conductive adhesive paste, the photovoltaic structures can be transported by conveyor 1210 to cleaving system 1206, which can cleave the photovoltaic structures into strips along the grooves formed by scribing tool 1202. After a photovoltaic structure is cleaved into a number of (e.g., three) strips, the strips can be transferred to string-arrangement system 1208. In some embodiments, the photovoltaic structures may be rotated 90° by a robotic arm (not shown in FIG. 12) before they are loaded to string-arrangement system 1208. String-arrangement system 1208 can lift these strips and arrange the strips in a cascaded arrangement while moving the strips to string-processing table 1212. String-arrangement system 1208 can overlap a leading edge of the three cascaded strips over the trailing edge of a previously formed string 1214, thereby extending string 1214.

The sequence of operations shown in FIG. 12 is one of many ways to manufacture cascaded strings. For example, the step of applying the conductive adhesive paste can occur before scribing or after cleaving. Furthermore, a variety of apparatuses and systems can be used to implement the functions shown in FIG. 12.

In addition to the conveyor belts shown in FIG. 12, other types of wafer transportation apparatus can be used to carry photovoltaic structures from one processing station to the next. For example, roller- or chain-driven conveyor, or walking beams can also be used to transport photovoltaic structures or individual strips between processing stations.

To summarize, embodiments of the invention provide a photovoltaic structure cleaving system that can cleave a photovoltaic structure into two or more strips with precision, with high throughput, and with little damage to the photovoltaic structure. The system can be configured to operate automatically, which can allow the system to be used for high-volume production.

Because the forces used for cleaving the photovoltaic structure are applied at locations adjacent to but away from the scribed grooves, there is no requirement for precise alignment of the photovoltaic structure. This cleaving system can be used as part of an assembly line for automated manufacturing of solar panels, or can be used as a stand-alone system. Moreover, various actuation methods and systems can be used for any moving part in this cleaving system, including but not limited to: a servo-motor or stepper-motor based actuation system, a hydraulic system, a piezoelectric system, a pneumatic system or any combination thereof.

The data structures and code described in this detailed description are typically stored on a computer-readable storage medium, which may be any device or medium that can store code and/or data for use by a computer system. The computer-readable storage medium includes, but is not limited to, volatile memory, non-volatile memory, magnetic and optical storage devices such as disk drives, magnetic tape, CDs (compact discs), DVDs (digital versatile discs or digital video discs), or other media capable of storing computer-readable media now known or later developed.

The methods and processes described in the detailed description section can be embodied as code and/or data, which can be stored in a computer-readable storage medium as described above. When a computer system reads and executes the code and/or data stored on the computer-readable storage medium, the computer system performs the methods and processes embodied as data structures and code and stored within the computer-readable storage medium.

Furthermore, the methods and processes described above can be included in hardware modules. For example, the hardware modules can include, but are not limited to, application-specific integrated circuit (ASIC) chips, field-programmable gate arrays (FPGAs), and other programmable-logic devices now known or later developed. When the hardware modules are activated, the hardware modules perform the methods and processes included within the hardware modules.

The foregoing descriptions of embodiments of the invention have been presented for purposes of illustration and description only. They are not intended to be exhaustive or to limit the invention to the forms disclosed. Accordingly, many modifications and variations will be apparent to practitioners skilled in the art. Additionally, the above disclosure is not intended to limit the invention. The scope of the invention is defined by the appended claims.

What is claimed is:

1. An apparatus for cleaving a photovoltaic structure into multiple strips, the apparatus comprising:
a supporting post; and
a cleaving platform for cleaving the photovoltaic structure;
wherein the cleaving platform is coupled to the supporting post via a translation stage;
wherein the cleaving platform comprises multiple platform segments that are configured to move relative to each other during cleaving; and
wherein each of the multiple platform segments comprises a wafer-holding surface for holding at least a portion of the photovoltaic structure.

2. The apparatus of claim 1, wherein prior to cleaving the photovoltaic structure the cleaving platform is configured to hold the photovoltaic structure with wafer-holding surfaces of the multiple platform segments substantially aligned.

3. The apparatus of claim 2, wherein the photovoltaic structure is held in such a way that a scribed groove on the photovoltaic structure is substantially parallel to and positioned below a gap separating two adjacent platform segments.

4. The apparatus of claim 1, wherein at least one platform segment of the cleaving platform is configured to rotate around an adjacent edge of an adjacent platform segment during cleaving.

5. The apparatus of claim 1, wherein the multiple platform segments include a stationary center segment and two movable side segments positioned on each side of the stationary center segment.

6. The apparatus of claim 5, wherein the two movable side segments are configured to rotate around adjacent edges of the stationary center segment to cleave the photovoltaic structure into three strips.

7. The apparatus of claim 6, further comprising a vertical actuator coupled to each movable side segment via a cam-follower mechanism, wherein the cam-follower mechanism is configured to convert vertical movements of the vertical actuator to rotations of the movable side segments.

8. The apparatus of claim 1, wherein the wafer-holding surface comprises a plurality of vacuum cups configured to apply a suction force on the portion of the photovoltaic structure.

9. The apparatus of claim 1, wherein the multiple platform segments comprise a stationary platform segment and at least one movable platform segment, wherein the apparatus further comprises a counterforce-applying mechanism, and wherein at least a portion of the photovoltaic structure is sandwiched between the counterforce-applying mechanism and the stationary platform segment during cleaving.

10. The apparatus of claim 1, further comprising a conveyor configured to transport the photovoltaic structure to a position below the cleaving platform to allow the cleaving platform to be lowered by the translation stage to pick up the photovoltaic structure.

11. An automatic cleaving system for cleaving a photovoltaic structure into multiple strips, the cleaving system comprising:
a segmented cleaving platform; and
a conveyor for transporting the photovoltaic structure to a position corresponding to the segmented cleaving platform;
wherein the segmented cleaving platform comprises a wafer-picking-up mechanism configured to pick up the photovoltaic structure from the conveyor; and
wherein the segmented cleaving platform comprises multiple platform segments that are configured to move relative to each other during cleaving.

12. The automatic cleaving system of claim 11, wherein the wafer-picking-up mechanism is further configured to pick up the photovoltaic structure in such a way that a scribed groove on the photovoltaic structure is substantially parallel to and positioned below a gap separating two adjacent platform segments.

13. The automatic cleaving system of claim 11, wherein at least one platform segment of the cleaving platform is configured to rotate around an adjacent edge of an adjacent platform segment during cleaving.

14. The automatic cleaving system of claim 11, wherein the multiple platform segments include a stationary center segment and two movable side segments positioned on each side of the stationary center segment.

15. The automatic cleaving system of claim 14, wherein the two movable side segments are configured to rotate around adjacent edges of the stationary center segment to cleave the photovoltaic structure into three strips.

16. The automatic cleaving system of claim 14, further comprising a vertical actuator coupled to each movable side segment via a cam-follower mechanism, wherein the cam-follower mechanism is configured to convert vertical movements of the vertical actuator to rotations of the movable side segments.

17. The automatic cleaving system of claim 11, wherein the multiple platform segments comprise a stationary platform segment and at least one movable platform segment, wherein the automatic cleaving system further comprises a counterforce-applying mechanism, and wherein at least a portion of the photovoltaic structure is sandwiched between the counterforce-applying mechanism and the stationary platform segment during cleaving.

18. The automatic cleaving system of claim 11, further comprising a translation stage coupled to the segmented cleaving platform, wherein the translation stage is configured to lower the segmented cleaving platform to pick up the photovoltaic structure from the conveyor.

19. A method for automatically cleaving a photovoltaic structure into multiple strips, the method comprising:
picking up, by a segmented cleaving platform, the photovoltaic structure from the conveyor, wherein the photovoltaic structure includes two scribed grooves, and wherein the segmented cleaving platform includes a stationary center platform segment and two side platform segments positioned on each side of the center platform segment; and
rotating the two side platform segments around corresponding edges of the stationary center platform segment to cleave the photovoltaic structure into three strips.

20. The method of claim 19, wherein rotating the two side platform segments involves activating a vertical actuator, which is coupled to each side platform segment via a cam-follower mechanism.
